(19) United States
(12) Patent Application Publication
(10) Pub. No.: US 2026/0090114 A1
(43) Pub. Date: Mar. 26, 2026

(54) BACK-ILLUMINATED LIGHT RECEIVING DEVICE

(71) Applicant: Mitsubishi Electric Corporation, Tokyo (JP)

(72) Inventor: Ryota TAKEMURA, Tokyo (JP)

(73) Assignee: Mitsubishi Electric Corporation, Tokyo (JP)

(21) Appl. No.: 19/107,925

(22) PCT Filed: Jan. 16, 2023
(86) PCT No.: PCT/JP2023/001037

§ 371 Date: Feb. 28, 2025

(51) Int. Cl. H10F 30/221; H10F 77/124

(52) U.S. Cl. CPC H10F 30/2215; H10F 77/1248

(57) ABSTRACT

An n-type contact layer (2), a p-type lightly-doped light absorption layer (3), an n-type lightly-doped light absorption layer (4), and a window layer (5) are stacked in order on a substrate (1). A p-type region (7) is formed in a part of the window layer (5) and the n-type lightly-doped light absorption layer (4).

### FIELD

The present disclosure relates to a back-illuminated light receiving device used for optical fiber communication and the like.

### BACKGROUND ART

A photodiode is a semiconductor light receiving device used for optical fiber communication and the like. Representative structures of the photodiode include a mesa structure and a planar structure. In the mesa structure, a peripheral part of a light receiving portion previously formed to have an epitaxial stacked structure is etched and removed to define a size of the light receiving portion that can receive light. In the planar structure, a layer called a window layer is partially converted into a p-type layer or an n-type layer to form a light receiving portion. The planar structure has a small leak current and is generally advantageous in terms of reliability because pin junction of the light receiving portion is not exposed to a front surface or a side surface of the device.

As described above, in the planar structure, it is necessary to convert a part of an epitaxial layer into a p-type layer or an n-type layer. However, in a compound semiconductor process, it is easy to partially converting the epitaxial layer into a p-type layer as compared with a case of partially converting the epitaxial layer into an n-type layer. In addition, controllability is also high. Therefore, p-i-n-junction in which a substrate side of the epitaxial layer is an n-type and a region partially provided on the front surface side is a p-type is often adopted.

It is generally necessary for the window layer to allow incident light to pass therethrough and to protect the front surface of the device. Therefore, a material greater in bandgap than a light absorption layer is used for the window layer. Thus, difference of the bandgap occurs at an interface between the window layer and the light absorption layer. The p-type region is often formed up to below the interface between the window layer and the light absorption layer such that movement of carriers at the interface between the window layer and the light absorption layer is not inhibited. At this time, the light absorption layer of the photodiode is often lightly-doped with an n-type dopant in order to stabilize a shape of the p-type region (for example, see PTL 1).

Further, the structure of the semiconductor light receiving device is roughly classified into a front-illuminated light receiving device receiving light from the front surface side of the epitaxial layer, a back-illuminated light receiving device receiving light from a back surface side of the substrate, and a side-illuminated light receiving device receiving light from a side surface. The back-illuminated light receiving device is often used, in particular, in a field where a communication speed is high, because both high-speed operation and a large light receiving diameter are easily achievable. In the back-illuminated light receiving device, light is largely absorbed on a side of the light absorption layer close to the substrate because of a light incident direction. Therefore, a large number of carriers are generated at that portion.

### PATENT LITERATURE

[PTL 1] JP 4956944 B

### SUMMARY

### Technical Problem

In a common back-illuminated light receiving device in which the light absorption layer is doped with an n-type dopant, electric field intensity on the side of the light absorption layer close to the substrate is small. However, a large quantity of light is absorbed in the region where the electric field intensity is small, and accordingly a large number of carriers are generated. In particular, in a case where input light is strong, the generated carriers stagnate, and a space-charge effect in which an electric field acts in a direction cancelling the electric field applied to the light absorption layer. Therefore, there is a problem that the carriers do not move, and high-speed responsiveness is deteriorated. When an application voltage from an outside is increased, the electric field can be increased and deterioration of high-speed responsiveness can be suppressed, but the application voltage is limited in use.

The present disclosure has been made to solve the above-described problem, and an object of the present disclosure is to provide a back-illuminated light receiving device that can enhance high-speed responsiveness without increasing an application voltage in a case where input light is strong.

A semiconductor device according to the present disclosure includes: a substrate; an n-type contact layer, a p-type lightly-doped light absorption layer, an n-type lightly-doped light absorption layer, and a window layer which are stacked in order on the substrate; and a p-type region formed in a part of the window layer and the n-type lightly-doped light absorption layer.

Other semiconductor device according to the present disclosure includes: a substrate; an n-type contact layer, a first n-type lightly-doped light absorption layer, a p-type doped light absorption layer, a second n-type lightly-doped light absorption layer, and a window layer which are stacked in order on the substrate; and a p-type region formed in a part of the window layer and the second n-type lightly-doped light absorption layer.

### Advantageous Effects of Invention

In the present disclosure, in the back-illuminated light receiving device in which the light absorption layer is doped with an n-type dopant, the substrate side of the light absorption layer is converted into a p-type layer. Therefore, electric field intensity of the substrate side of the light absorption layer can be increased, which makes it possible to suppress the space-charge effect.

As a result, high-speed responsiveness in a case where input light is strong can be enhanced without increasing the application voltage.

### BRIEF DESCRIPTION OF THE DRAWINGS

FIG. 1 is a cross-sectional view illustrating a semiconductor light receiving device according to Embodiment 1.

FIG. 2 is a cross-sectional view illustrating Modification 1 of the semiconductor light receiving device according to Embodiment 1.

FIG. 3 is a cross-sectional view illustrating Modification 2 of the semiconductor light receiving device according to Embodiment 1.

FIG. 4 is a cross-sectional view illustrating a semiconductor light receiving device according to a comparative example.

FIG. 5 is a diagram illustrating electric field intensity distribution of a portion depleted in a case where a voltage is applied to the semiconductor light receiving device according to each of Embodiment 1 and the comparative example.

FIG. 6 is a cross-sectional view illustrating Modification 3 of the semiconductor light receiving device according to Embodiment 1.

FIG. 7 is a cross-sectional view illustrating a semiconductor light receiving device according to Embodiment 3.

FIG. 8 is a diagram illustrating electric field intensity distribution of a portion depleted in a case where a voltage is applied to the semiconductor light receiving device according to each of Embodiment 3 and the comparative example.

FIG. 9 is a cross-sectional view illustrating a semiconductor light receiving device according to Embodiment 4.

FIG. 10 is a diagram illustrating electric field intensity distribution of a portion depleted in a case where a voltage is applied to the semiconductor light receiving device according to each of Embodiment 4 and the comparative example.

FIG. 11 is a cross-sectional view illustrating a semiconductor light-receiving device according to Embodiment 5.

### DESCRIPTION OF EMBODIMENTS

A back-illuminated light receiving device according to the embodiments of the present disclosure will be described with reference to the drawings. The same components will be denoted by the same symbols, and the repeated description thereof may be omitted.

### Embodiment 1

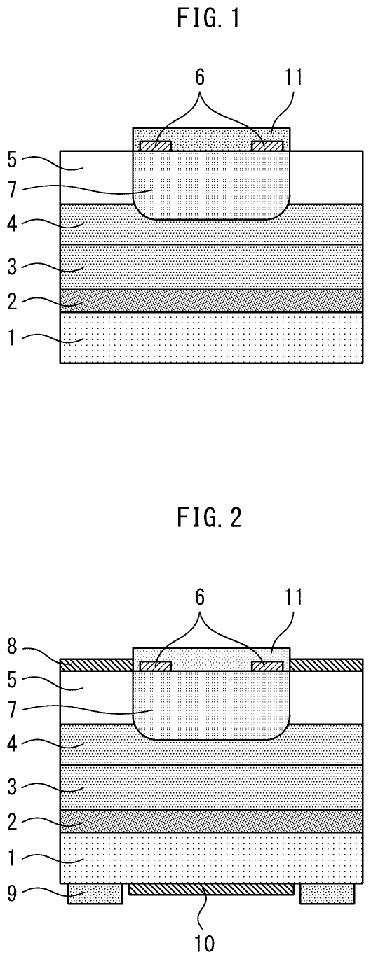

FIG. 1 is a cross-sectional view illustrating a semiconductor light receiving device according to Embodiment 1. An n-type contact layer 2, a p-type lightly-doped light absorption layer 3, an n-type lightly-doped light absorption layer 4, a window layer 5, and a p-type contact layer 6 are stacked in order on an InP substrate 1. Note that lightly-doped means impurity concentration of 5×10¹⁷ cm⁻³ or less. Therefore, impurity concentration of each of the p-type lightly-doped light absorption layer 3 and the n-type lightly-doped light absorption layer 4 is 5×10¹⁷ cm⁻³ or less.

A p-type region 7 is continuously formed in a part of the window layer 5 and the n-type lightly-doped light absorption layer 4 from a front surface side of an epitaxial layer, and functions as a light receiving portion. A p-type electrode metal 11 is formed so as to be conductive with at least the p-type contact layer 6, and functions as an anode. A planar structure in which the p-type region 7 is partially formed later in the above-described manner is excellent in reliability as compared with a mesa structure.

Examples of a material of the n-type contact layer 2 include InGaAs, InP, InGaAsP, AlInAs, AlGaInAs, and a combination thereof. A material of the p-type lightly-doped light absorption layer 3 and the n-type lightly-doped light absorption layer 4 is a material generating carriers when light enters the layers, namely, a material having a small bandgap to incident light. Examples of such a material include InGaAs, InGaAsP, InGaAsSb, and a combination thereof. A material of the window layer 5 is a material allowing the incident light to pass therethrough, and examples of such a material include InP, InGaAsP, AlInAs, AlGaInAs, and a combination thereof. Examples of a material of the p-type contact layer 6 include InGaAs, InP, InGaAsP, AlInAs, AlGaInAs, and a combination thereof. To relax band discontinuity, a band discontinuity relaxation layer made of InGaAsP, AlGaInAs, or the like may be provided between epitaxial layers or between the p-type electrode metal 11 and the epitaxial layer. Any material may be used for each layer as long as characteristics necessary for operation of the semiconductor light receiving device can be obtained, and the above-described materials do not limit the range.

As a p-type dopant imparting conductivity to a group III-V semiconductor crystal, a group II atom such as Be, Mg, Zn, and Cd is used. As an N-type dopant, a group IV atom such as S, Se, and Te is used. As an amphoteric impurity functioning as a dopant of any conductive type by the semiconductor crystal, a group IV atom such as C, Si, Ge, and Sn is used.

FIG. 2 is a cross-sectional view illustrating Modification 1 of the semiconductor light receiving device according to Embodiment 1. A side surface and an upper surface of the epitaxial layer are covered with a passivation film 8. Examples of a material of the passivation film 8 include SiO₂, SiN, SiON, and a combination thereof. A portion not inhibiting incidence of light, of a back surface of the substrate is covered with a back surface metal 9. The InP substrate 1 is of an n-type, and the back surface metal 9 function as a cathode. An antireflection film 10 is provided in a portion receiving light, of the back surface of the substrate. The p-type contact layer 6 has a ring shape as viewed from an upper surface side, but may have a circular shape.

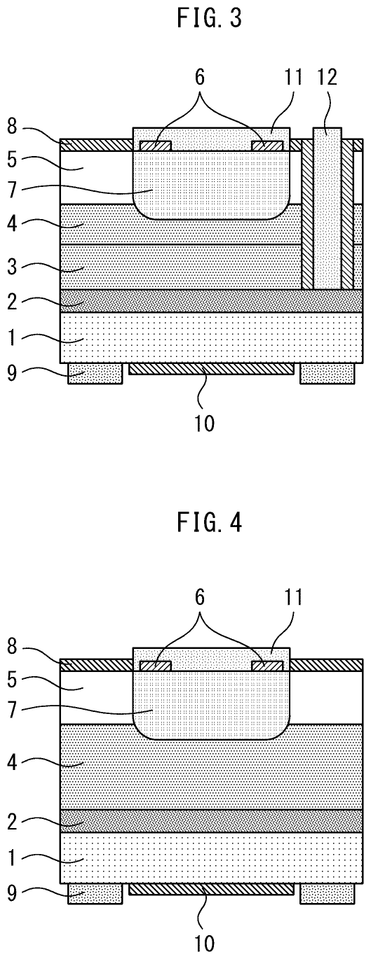

FIG. 3 is a cross-sectional view illustrating Modification 2 of the semiconductor light receiving device according to Embodiment 1. In Modification 2, the InP substrate 1 has semi-insulating property. A cathode metal 12 is provided on the front surface side of the epitaxial layer so as to come into contact with the n-type contact layer 2, and functions as a cathode.

Subsequently, a method of manufacturing the semiconductor light receiving device according to Embodiment 1 is described. First, the epitaxial layer is grown on the InP substrate 1 by using a growth method such as a liquid phase epitaxy (LPE) method, a vapor phase epitaxy (VPE) method, in particular, a metal organic VPE (MO-VPE) method, and a molecular beam epitaxy (MBE) method.

Thereafter, in a state where a mask only in a desired portion is opened by using a common lithography technique, the p-type region 7 is formed by diffusing a p-type dopant such as Zn in a vapor phase or a solid phase. Thereafter, in a state where a mask only in a desired portion is opened by using a common lithography technique, a film of a metal material such as Ti, Pt, and Au is formed by a method such as electron beam vapor deposition and sputtering, and the metal material in an unnecessary portion is removed to form the p-type electrode metal 11 and the cathode metal 12. Note that the p-type electrode metal 11 and the cathode metal 12 can be formed in such a manner that, after the film of the metal material is formed on the entire surface, the metal material in the unnecessary portion is etched in a state where the mask remains only in the desired portion by using a common lithography technique.

After an insulating film is formed by a method such as a plasma-enhanced chemical vapor deposition (PE-CVD) method and sputtering, the insulating film in an unnecessary portion is etched in a state where a mask remains only in a desired portion by using a common lithography technique, to form the passivation film 8.

Thereafter, the InP substrate 1 is inverted and fixed to another support substrate or the like. A film of a metal material such as Ti, Pt, Ni, and Au is formed by a method such as electron beam vapor deposition and sputtering in a state where a mask only in a desired portion is opened by using a common lithography technique, and the metal material in an unnecessary portion is removed to form the back surface metal 9. Note that the back surface metal 9 can be formed in such a manner that, after the film of the metal material is formed on the entire surface, the metal material in the unnecessary portion is etched in a state where the mask remains only in the desired portion by using a common lithography technique.

Thereafter, the InP substrate 1 is inverted and fixed to another support substrate or the like. After an insulating film is formed by a method such as a PE-CVD method and sputtering, the insulating film in an unnecessary portion is etched in a state where a mask remains only in a desired portion by using a common lithography technique, to form the antireflection film 10.

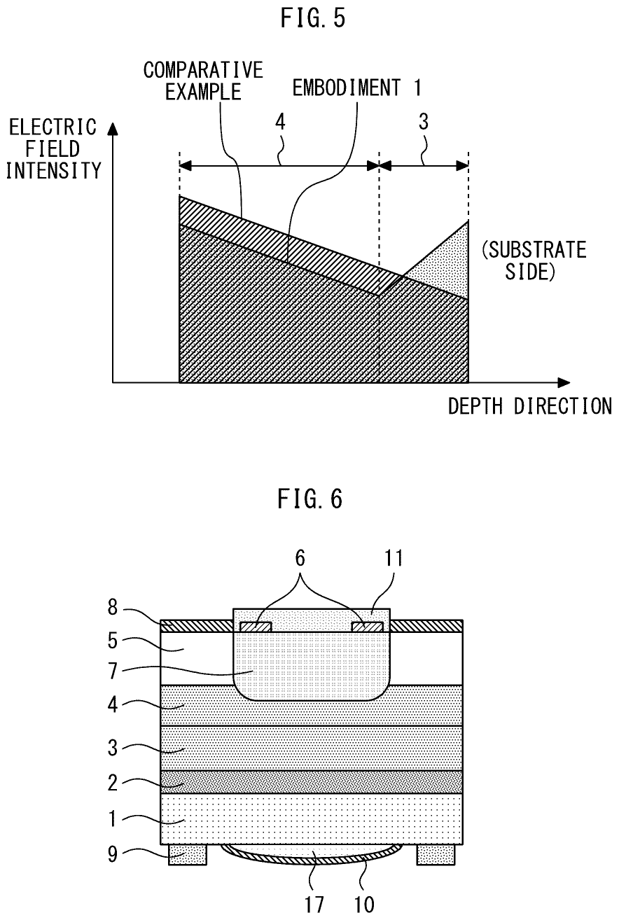

Effects by the present embodiment are described while being compared with a comparative example. FIG. 4 is a cross-sectional view illustrating a semiconductor light receiving device according to a comparative example. In the comparative example, the p-type lightly-doped light absorption layer 3 on a lower part of the light absorption layer is not provided, and the light absorption layer includes only the n-type lightly-doped light absorption layer 4. FIG. 5 is a diagram illustrating electric field intensity distribution of a portion depleted in a case where a voltage is applied to the semiconductor light receiving device according to each of Embodiment 1 and the comparative example. In the comparative example, electric field intensity in a region close to the InP substrate 1 is small. In contrast, in Embodiment 1, electric field intensity in the region close to the InP substrate 1 is higher than electric field intensity according to the comparative example. Therefore, even in a case where strong light enters and a large number of carriers are generated in the region of the light absorption layer close to the substrate, a space-charge effect hardly occurs, and deterioration of frequency characteristics can be prevented.

As described above, in the present embodiment, in the back-illuminated light receiving device in which the light absorption layer is doped with an n-type dopant, the substrate side of the light absorption layer is converted into a p-type layer. Therefore, electric field intensity of the substrate side of the light absorption layer can be increased, which makes it possible to suppress the space-charge effect. As a result, high-speed responsiveness in a case where input light is strong can be enhanced without increasing the application voltage.

When the impurity concentration of the p-type lightly-doped light absorption layer 3 is increased, the application voltage necessary for depletion is increased. Therefore, the impurity concentration of the p-type lightly-doped light absorption layer 3 is desirably 1×10¹⁷ cm⁻³ or less because of a practical issue.

Further, since the p-type lightly-doped light absorption layer 3 and the n-type lightly-doped light absorption layer 4 absorb light, each of the p-type lightly-doped light absorption layer 3 and the n-type lightly-doped light absorption layer 4 is required to have a certain thickness. To achieve the effects of the present embodiment while improving sensitivity, the n-type lightly-doped light absorption layer 4 desirably has a thickness of 0.3 μm or more.

FIG. 6 is a cross-sectional view illustrating Modification 3 of the semiconductor light receiving device according to Embodiment 1. A back surface lens 17 is provided on a back surface of the InP substrate 1 on a side opposite to the front surface provided with the epitaxial layer. The back surface lens 17 can be formed in various methods such as isotropic wet etching or dry etching in a state where a lens center part is covered with a mask, dry etching while changing an etching mask diameter, and etching in a state where a photoresist is formed in a lens shape. The back surface lens 17 condenses the incident light on the p-type region 7. Therefore, an apparent light receiving diameter can be expanded. Thus, the structure is used for a high-speed communication device in which the p-type region 7 is reduced to achieve low capacity.

On the other hand, light density in a part is increased and the space-charge effect is likely to occur because of light condensation; however, a higher effect of suppressing the space-charge effect can be achieved by the structure according to Embodiment 1. In embodiments described below, the higher effect of suppressing the space-charge effect can be achieved by the structure including the back surface lens 17.

### Embodiment 2

In Embodiment 1, the p-type lightly-doped light absorption layer 3 and the n-type lightly-doped light absorption layer 4 are made of the same semiconductor material having the bandgap absorbing the incident light. In the present embodiment, bandgap energy of the p-type lightly-doped light absorption layer 3 is greater than bandgap energy of the n-type lightly-doped light absorption layer 4. As a result, an absorption coefficient of the p-type lightly-doped light absorption layer 3 is reduced, and a light absorption quantity is reduced. Thus, concentration of carriers on a side of the light absorption layer close to the substrate is suppressed. This makes it possible to suppress the space-charge effect as compared with the configuration according to Embodiment 1. The other configurations and effects are similar to the configurations and effects according to Embodiment 1.

### Embodiment 3

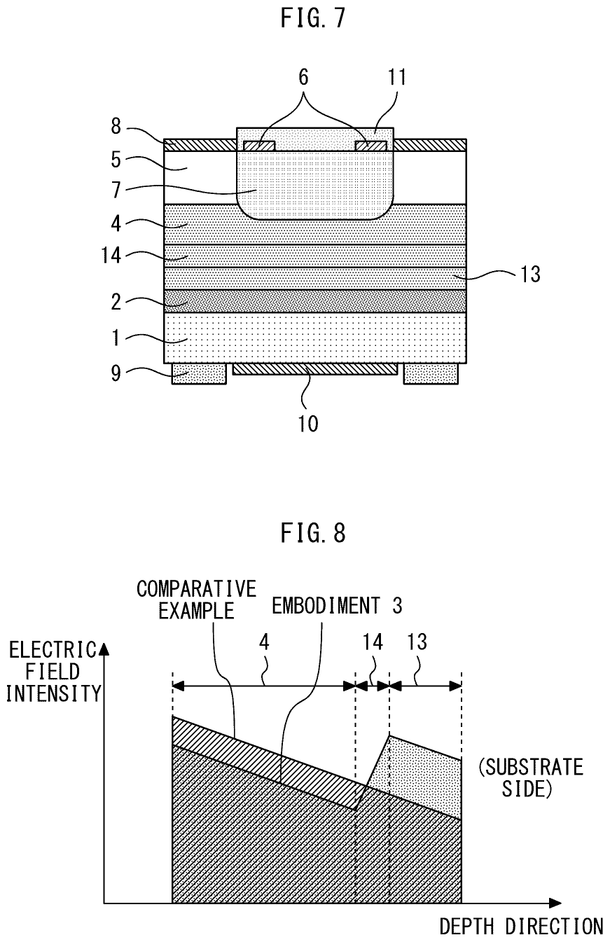

FIG. 7 is a cross-sectional view illustrating a semiconductor light receiving device according to Embodiment 3. In the present embodiment, a region of the p-type lightly-doped light absorption layer 3 according to Embodiment 1 close to the InP substrate 1 is replaced with a p-type doped light absorption layer 14 having high impurity concentration. An n-type lightly-doped light absorption layer 13 is provided between the p-type doped light absorption layer 14 and the n-type contact layer 2. The impurity concentration of each of the n-type lightly-doped light absorption layers 4 and 13 is 5×10¹⁷ cm⁻³ or less. The impurity concentration of the p-type doped light absorption layer 14 is 5×10¹⁷ cm⁻³ or more.

FIG. 8 is a diagram illustrating electric field intensity distribution of a portion depleted in a case where a voltage is applied to the semiconductor light receiving device according to each of Embodiment 3 and the comparative example. As in Embodiment 1, the electric field intensity in the region close to the InP substrate 1 is higher than the electric field intensity according to the comparative example. Therefore, even in a case where strong light enters and a large number of carriers are generated in the region of the light absorption layer close to the substrate, the space-charge effect hardly occurs, and deterioration of the frequency characteristics can be prevented.

When the n-type lightly-doped light absorption layer 13 is formed on an interface on a back surface side of the light absorption layer, electric field intensity near the interface is reduced. However, the light entering from the back surface of the substrate is not wholly absorbed by the interface on the back surface side of the light absorption layer, but is gradually absorbed as it travels from the interface toward the inside of the light absorption layer. In the present embodiment, using the p-type doped light absorption layer 14 having high impurity concentration makes it possible to enhance the electric field intensity within a range of a certain thickness on the back surface side of the light absorption layer. Therefore, deterioration of the frequency characteristics can be prevented.

### Embodiment 4

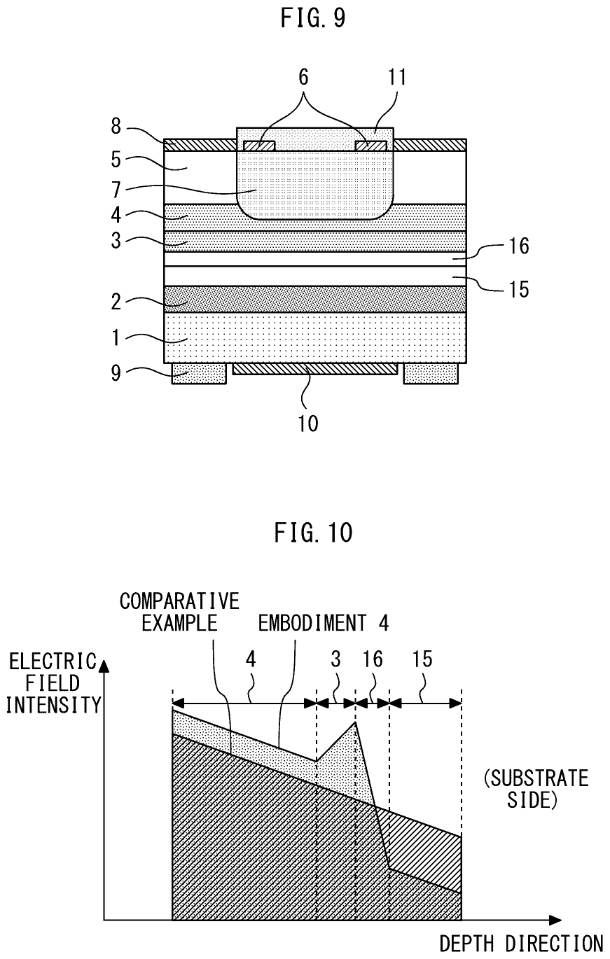

FIG. 9 is a cross-sectional view illustrating a semiconductor light receiving device according to Embodiment 4. An n-type lightly-doped electron transit layer 15 is inserted between the n-type contact layer 2 and the p-type lightly-doped light absorption layer 3. An n-type doped layer 16 is inserted between the n-type lightly-doped electron transit layer 15 and the p-type lightly-doped light absorption layer 3. The n-type lightly-doped electron transit layer 15 and the n-type doped layer 16 are continuous with each other, but a band discontinuity relaxation layer may be inserted therebetween.

The n-type lightly-doped electron transit layer 15 and the n-type doped layer 16 are made of a material not absorbing the incident light, for example, InP, InGaAsP, AlInAs, AlGaInAs, or a combination thereof.

When the light absorption layer absorbs light, electrons and holes are generated. The holes move to the anode side to which a minas voltage is applied, and the electrons move to the cathode side to which a plus voltage is applied. Among the carriers generated in the light absorption layer, only the electrons having moved to the substrate side move in the n-type lightly-doped electron transit layer 15. It is necessary to apply a small electric field to the n-type lightly-doped electron transit layer 15. Therefore, the impurity concentration of the n-type lightly-doped electron transit layer 15 is set to 1×10¹⁶ cm⁻³ or less.

The n-type doped layer 16 adjusts the electric field applied to the n-type lightly-doped electron transit layer 15. The impurity concentration of the n-type doped layer 16 is higher than the impurity concentration of the n-type lightly-doped electron transit layer 15, and is lower than the impurity concentration of the n-type contact layer 2. To reduce a resistance at contact with the cathode electrode, the impurity concentration of the n-type contact layer 2 is set to 1×10¹⁸ cm⁻³ or more.

Along with increase in information communication quantity in recent years, improvement in high-speed responsiveness of the photodiode is desired. To do so, it is necessary to achieve both low capacity and reduction of a carrier transit time. To achieve both the low capacity and reduction of the carrier transit time, in the present embodiment, the n-type lightly-doped electron transit layer 15 not absorbing light is inserted below the light absorption layer.

In the case where the n-type lightly-doped electron transit layer 15 is inserted, a moving distance of the electrons is increased, and a moving time of the electrons becomes long, but a moving time of the holes is not changed. A moving speed of the holes is many times slower than the moving speed of the electrons. Thus, the moving time of the holes controls the entire high-speed responsiveness. Since only the electrons move in the n-type lightly-doped electron transit layer 15, the carrier transit time is not substantially increased. Therefore, even when the n-type lightly-doped electron transit layer 15 is inserted, the entire high-speed responsiveness is not affected. On the other hand, a width of the depletion layer is increased by the thickness of the inserted n-type lightly-doped electron transit layer 15. This makes it possible to reduce the capacity. Therefore, it is possible to achieve both the low capacity and reduction of the carrier transit time.

Further, the moving speed of the electrons is increased as the electric field intensity of the n-type lightly-doped electron transit layer 15 is lower. The thickness of the n-type lightly-doped electron transit layer 15 can be increased and the capacity can be reduced as the moving speed of the electrons is increased, which is advantageous for high-speed operation. Adding the n-type doped layer 16 makes it possible to reduce the electric field intensity of the n-type lightly-doped electron transit layer 15.

FIG. 10 is a diagram illustrating electric field intensity distribution of a portion depleted in a case where a voltage is applied to the semiconductor light receiving device according to each of Embodiment 4 and the comparative example. As in Embodiment 1, the electric field intensity in the region close to the InP substrate 1 is higher than the electric field intensity according to the comparative example. Therefore, even in a case where strong light enters and a large number of carriers are generated in the region of the light absorption layer close to the substrate, the space-charge effect hardly occurs, and deterioration of the frequency characteristics can be prevented.

Although the electric field intensity of the n-type lightly-doped electron transit layer 15 is reduced, it is known that a drift speed of the electrons is specifically high in a region where the electric field intensity is low. Therefore, the drift speed of the electrons is increased, and the high-speed responsiveness can be further improved.

### Embodiment 5

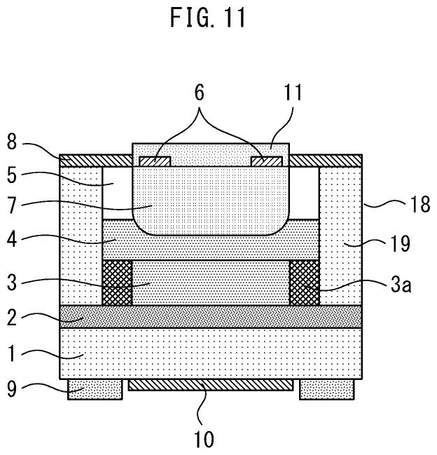

FIG. 11 is a cross-sectional view illustrating a semiconductor light-receiving device according to Embodiment 5. A trench 18 is formed from the window layer 5 to a lower layer of the p-type lightly-doped light absorption layer 3 on the outside of the p-type region 7 in a planar view, by at least one etching. The trench 18 is embedded by a semiconductor embedding layer 19. The semiconductor embedding layer 19 is made of, for example, InP. When the trench 18 is formed, the capacity can be reduced, and the high-speed responsiveness is improved. However, a leak current may flow through an interface between the semiconductor embedding layer 19 and an etching side surface portion.

Therefore, the impurity concentration of a peripheral part 3a of the p-type lightly-doped light absorption layer 3 in contact with the trench 18 is made lower than the impurity concentration of a center part of the p-type lightly-doped light absorption layer 3. As a result, the electric field intensity of the peripheral part of the p-type lightly-doped light absorption layer 3 in contact with the trench 18 can be reduced while the electric field intensity of the center part of the light receiving portion where the light enters and a large number of carriers are generated is increased. This makes it possible to reduce the leak current. The other configurations and effects are similar to the configurations and effects according to Embodiment 1.

### REFERENCE SIGNS LIST

1 InP substrate 1 (substrate); 2 n-type contact layer; 3 p-type lightly-doped light absorption layer; 3a peripheral part; 4 n-type lightly-doped light absorption layer (second n-type lightly-doped light absorption layer); 5 window layer; 7 p-type region; 13 n-type lightly-doped light absorption layer (first n-type lightly-doped light absorption layer); 14 p-type doped light absorption layer; 15 n-type lightly-doped electron transit layer(n-type electron transit layer); 16 n-type doped layer; 18 trench; 19 semiconductor embedding layer

1. A back-illuminated light receiving device comprising:
a substrate;
an n-type contact layer, a p-type lightly-doped light absorption layer, an n-type lightly-doped light absorption layer, and a window layer which are stacked in order on the substrate; and
a p-type region formed in a part of the window layer and the n-type lightly-doped light absorption layer.

2. The back-illuminated light receiving device according to claim 1, wherein an impurity concentration of each of the p-type lightly-doped light absorption layer and the n-type lightly-doped light absorption layer is 5×10¹⁷ cm⁻³ or less.

3. The back-illuminated light receiving device according to claim 2, wherein an impurity concentration of the p-type lightly-doped light absorption layer is 1×10¹⁷ cm⁻³ or less.

4. The back-illuminated light receiving device according to claim 1, wherein the n-type lightly-doped light absorption layer has a thickness of 0.3 μm or more.

5. The back-illuminated light receiving device according to claim 1, wherein the p-type lightly-doped light absorption layer and the n-type lightly-doped light absorption layer are made of the same semiconductor material having a bandgap absorbing an incident light.

6. The back-illuminated light receiving device according to claim 1, wherein the p-type lightly-doped light absorption layer and the n-type lightly-doped light absorption layer are made of a semiconductor material having a bandgap absorbing an incident light, and
bandgap energy of the p-type lightly-doped light absorption layer is greater than bandgap energy of the n-type lightly-doped light absorption layer.

7. The back-illuminated light receiving device according to claim 1, further comprising an n-type electron transit layer inserted between the n-type contact layer and the p-type lightly-doped light absorption layer, and
an n-type doped layer inserted between the n-type electron transit layer and the p-type lightly-doped light absorption layer and having an impurity concentration higher than that of the n-type electron transit layer.

8. The back-illuminated light receiving device according to claim 1, wherein a trench is formed from the window layer to a lower layer of the p-type lightly-doped light absorption layer on the outside of the p-type region in a planar view, and
an impurity concentration of a peripheral part of the p-type lightly-doped light absorption layer in contact with the trench is lower than an impurity concentration of a center part of the p-type lightly-doped light absorption layer.

9. A back-illuminated light receiving device comprising:
a substrate;
an n-type contact layer, a first n-type lightly-doped light absorption layer, a p-type doped light absorption layer, a second n-type lightly-doped light absorption layer, and a window layer which are stacked in order on the substrate; and
a p-type region formed in a part of the window layer and the second n-type lightly-doped light absorption layer.

10. The back-illuminated light receiving device according to claim 9, wherein an impurity concentration of each of the first n-type lightly-doped light absorption layer and the second n-type lightly-doped light absorption layer is 5×10¹⁷ cm⁻³ or less.

11. The back-illuminated light receiving device according to claim 9, wherein the first n-type lightly-doped light absorption layer, the p-type doped light absorption layer and the second n-type lightly-doped light absorption layer are made of the same semiconductor material having a bandgap absorbing an incident light.
